(19) United States
(12) Patent Application Publication
(10) Pub. No.: US 2019/0333802 A1
(43) Pub. Date: Oct. 31, 2019

(54) ELECTRONIC DEVICE COMPRISING AN INSULATING TRENCH AND METHOD FOR THE PRODUCTION OF SAME

(71) Applicant: Aledia, Grenoble Cedex 9 (FR)

(72) Inventors: Thomas Lacave, Grenoble (FR); Philippe Gilet, Teche (FR)

(73) Assignee: Aledia, Grenoble Cedex 9 (FR)

(21) Appl. No.: 16/468,575

(22) PCT Filed: Dec. 6, 2017
(86) PCT No.: PCT/FR2017/053421

§ 371 Date: Jun. 11, 2019

(30) Foreign Application Priority Data
Dec. 12, 2016 (FR) 1662301

(51) Int. Cl. H01L 21/762; H01L 27/15; H01L 27/144; H01L 21/02

(52) U.S. Cl. CPC H01L 21/76224; H01L 27/15; H01L 27/144; H01L 21/02255; H01L 21/02274; H01L 21/02238; H01L 21/02164

(57) ABSTRACT

An electronic device including a semiconductor substrate having first and second opposite surfaces and including an electrical insulation trench extending in the substrate from the first surface to the second surface, the electrical insulation trench including lateral walls, an electrically-insulating layer covering the lateral walls, and a core made of a filling material separated from the substrate by the insulating layer and including an electrically-insulating portion extending in the substrate from the first surface and covering the core.

The present patent application claims the priority benefit of French patent application FR16/62301 which is herein incorporated by reference.

### BACKGROUND

The present invention generally concerns electronic devices and methods of manufacturing the same.

### DISCUSSION OF THE RELATED ART

For certain applications, it is desirable to be able to form electrical insulation trenches in a semiconductor substrate of an electronic circuit to electrically insulate substrate portions from one another. An example of application corresponds to the forming of optoelectronic devices made up of semiconductor materials. The term “optoelectronic devices” is used to designate devices capable of converting an electric signal into an electromagnetic radiation or conversely, and especially devices dedicated to detecting, measuring, or emitting an electromagnetic radiation, or devices dedicated to photovoltaic applications.

Optoelectronic devices may comprise optoelectronic components, for example, light-emitting diodes, formed on the semiconductor substrate. The electrical insulation trenches may be formed in the substrate to electrically insulate a substrate portion for each optoelectronic component.

FIG. 1 is a partial simplified cross-section view of an example of an electronic circuit 5 comprising a semiconductor substrate 10 having an upper surface 12 and a lower surface 13 and comprising an electrical insulation trench 14 which delimits two portions 16 and 18 of substrate 10. Trench 14 extends in substrate 10 from surface 12 to surface 13. Trench 14 comprises lateral walls 20. An electrically-insulating layer 24 covers the lateral walls 20 of trench 14. A core 26 made of a filling material, for example, a semiconductor material, fills the rest of trench 14, core 26 being separated from substrate 10 by insulating layer 24.

Electronic circuit 5 may further comprise, on surface 12, a layer 30 of a material promoting the forming of optoelectronic components, not shown. Layer 30 may be conductive and is, in this case, open at the level of trench 14. Electronic circuit 5 may further comprise an electrically-insulating layer or a stack of electrically-insulating layers covering surface 12 and/or surface 13 and trench 14. As an example, two electrically-insulating layers 32, 34 have been shown as an example in FIG. 1 on the side of surface 12 and in insulating layer 35 has been shown in the side of surface 13, for example in contact with surface 13. Electrically-conductive pads, not shown, may be provided on insulating layer 35 and through insulating layer 35 in contact with portions 16 and 18 of substrate 10.

Lateral walls 20 may be substantially parallel, as shown in FIG. 1. The term lateral dimension L, or width, of trench 14 designates the distance between the two lateral walls 20. As a variation, lateral walls 20 may be substantially inclined with respect to each other, lateral walls 20 for example coming closer to each other as the distance to surface 12 increases. In this case, width L of trench 14 corresponds to the average distance separating the two lateral walls. Call P the thickness of substrate 10, that is, the distance between surfaces 12 and 13, which substantially corresponds to the depth of trench 14 obtained after a step of thinning substrate 10. Further, call E the thickness of insulating layer 24. Insulating layer 24 may have a substantially constant thickness. As a variation, the thickness of insulating layer 24 may be non-constant. In this case, thickness E corresponds to the minimum thickness of insulating layer 24.

Width L and thickness E are determined according to the voltage behavior desired for trench 14, that is, the minimum voltage, called breakdown voltage, applied between portions 16 and 18 of substrate 10 at the level of the surface 12 for which trench 14 becomes electrically conductive. Dimensions L and E are generally determined by simulation.

However, in certain cases, the breakdown voltage really measured may be smaller than the breakdown voltage provided by simulation.

### SUMMARY

An object of an embodiment is to provide an electronic circuit comprising electrical insulation trenches overcoming all or part of the disadvantages of existing trenches.

Another object of an embodiment is to increase the breakdown voltage of electrical insulation trenches.

Another object of an embodiment is for the method of manufacturing electrical insulation trenches to comprise a small number of additional steps with respect to a method of manufacturing conventional electrical insulation trenches.

Another object of an embodiment is for the electrical insulation trenches to form neither bulged areas nor depressions on the upper surface of the substrate.

Thus, an embodiment provides an electronic device comprising a semiconductor substrate having first and second opposite surfaces and comprising an electrical insulation trench extending in the substrate from the first surface to the second surface, the electrical insulation trench comprising lateral walls, an electrically-insulating layer covering the lateral walls, and a core made of a filling material separated from the substrate by the insulating layer and comprising an electrically-insulating portion extending in the substrate from the first surface and covering the core.

According to an embodiment, the first surface is planar at the location of the electrical insulation trench.

According to an embodiment, the insulating portion is a thermal oxide.

According to an embodiment, the insulating portion is made of silicon oxide.

According to an embodiment, the filling material is polysilicon.

According to an embodiment, the electrically-insulating portion extends laterally in the substrate with respect to the rest of the electrical insulation trench.

According to an embodiment, the device comprises at least first and second optoelectronic components capable of emitting an electromagnetic radiation or of absorbing an electromagnetic radiation, the first optoelectronic component resting on a first portion of the substrate and the second optoelectronic component resting on a second portion of the substrate, the electrical insulation trench separating the first portion from the second portion.

An embodiment also provides a method of manufacturing an electronic device, such as previously defined, comprising the steps of:

(a) forming a first opening into the substrate from the first surface;

(b) forming a layer of the material of the electrically-insulating layer in the first opening and on the first surface;

(c) forming a layer of the filling material in the opening and on the first surface; and

(d) forming the insulating portion.

According to an embodiment, the step comprises a thermal oxidation step.

According to an embodiment, step (d) comprises a thermal oxidation step.

According to an embodiment, step (d) comprises a chemical vapor deposition step followed by a step of thermal anneal at more than 500° C.

According to an embodiment, the method further comprises a step (e) of etching the portions of the layer of the material of the electrically-insulating layer and of the layer of the filling material present on the first surface.

According to an embodiment, step (e) is carried out before step (d).

According to an embodiment, step (d) is carried out before step (e).

According to an embodiment, the method further comprises forming, before step (d), a second opening into the layer of the material of the electrically-insulating layer, the layer of the filling material on the first surface, and the substrate at the location of the insulation portion.

### BRIEF DESCRIPTION OF THE DRAWINGS

The foregoing and other features and advantages will be discussed in detail in the following non-limiting description of specific embodiments in connection with the accompanying drawings, among which:

FIG. 1, previously described, is a partial simplified cross-section view of an example of an electronic circuit comprising an electrical insulation trench;

FIGS. 2 and 3 are partial simplified cross-section views of embodiments of an electronic circuit comprising an electrical insulation trench;

FIGS. 4A to 4G are partial simplified cross-section views of structures obtained at successive steps of an embodiment of a method of manufacturing the electrical insulation trench of the electronic device of FIG. 2;

FIGS. 5A to 5C are partial simplified cross-section views of structures obtained at successive steps of another embodiment of a method of manufacturing the electrical insulation trench of the electronic circuit of FIG. 2; and

FIGS. 6A and 6B are partial simplified cross-section views of structures obtained at successive steps of another embodiment of a method of manufacturing the electrical insulation trench of the electronic circuit of FIG. 2.

### DETAILED DESCRIPTION

The same elements have been designated with the same reference numerals in the various drawings and, further, the various drawings are not to scale. In the following description, when reference is made to terms qualifying the relative position, such as term “top”, “bottom”, “upper”, “lower”, etc., reference is made to the orientation of drawings or to an electronic device in a normal position of use.

For clarity, only those steps and elements which are useful to the understanding of the described embodiments have been shown and are detailed. In particular, the electronic components of an electronic circuit are well known in the art and are not described in detail hereafter. In the following description, expressions “substantially”, “around”, and “approximately” mean “to within 10%”, preferably to within 5%.

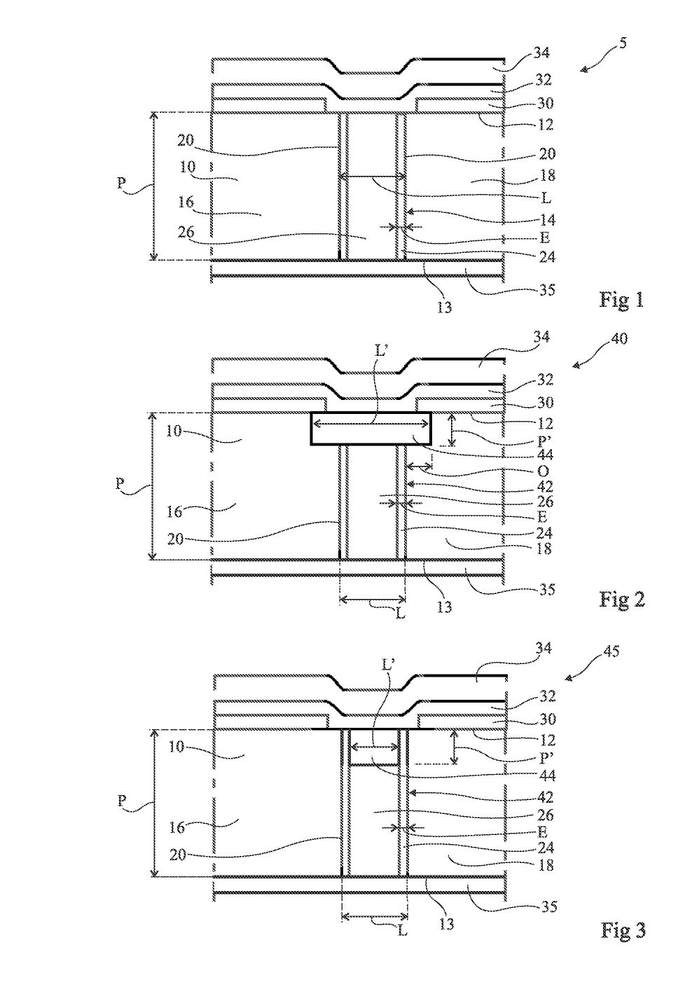

The inventors have shown that, for the electrical insulation trench structure 14 shown in FIG. 1, an electric arc particularly tends to form in case of a breakdown between portion 16 or 18 and core 26 through insulating layer 32 at the top of insulating layer 24. An explanation would be that insulating layer 32 is generally made of an electrically-insulating material having poorer electronic properties than the electrically-insulating material forming insulating layer 24, particularly due to the method of manufacturing the insulating layers. Another explanation would be that the geometry of the device causes point effects (electrostatic field having an amplitude locally higher than elsewhere) which favor the forming of electric arcs in case of a breakdown between portion 16 or 18 and core 26 through insulating layer 32 at the top of insulating layer 24.

An embodiment provides increasing the electrical insulation at the top of the electrical insulation trench to avoid the forming of an electric arc in this area. This enables to increase the breakdown voltage of the electrical insulation trench, and thus the maximum voltage of the electronic circuit.

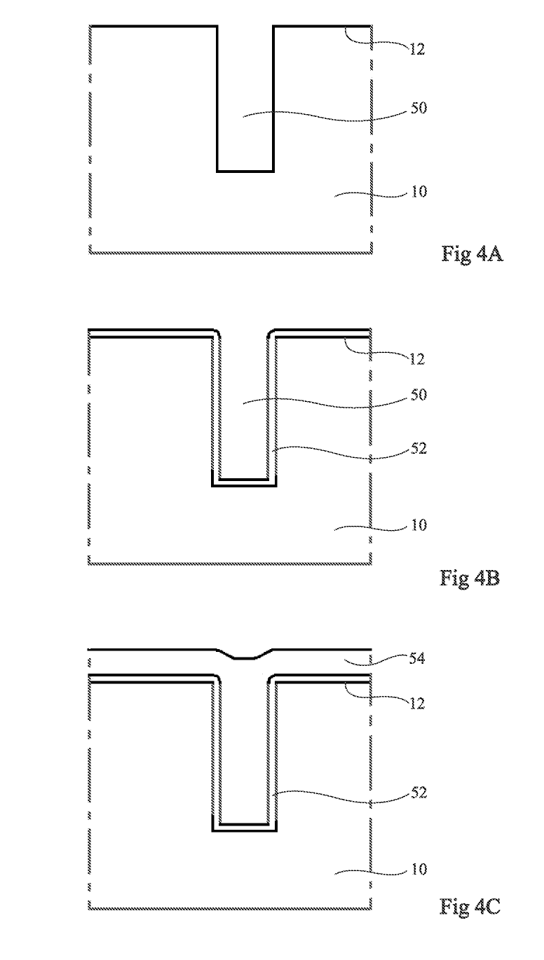

FIG. 2 shows an embodiment of an electronic circuit 40 comprising an electrical insulation trench 42. Trench 42 comprises all the elements of trench 14 shown in FIG. 1 and further comprises an electrically-insulating buried portion 44 which extends in substrate 10 from surface 12 down to a depth P′ smaller than depth P of trench 42 and which covers insulating layer 24 and core 26. Call L′ the lateral dimension, also called width, of insulating portion 44. Width L of trench 42 corresponds to the width, such as previously defined for trench 14, of trench 42 in the absence of insulating portion 44. According to an embodiment, insulating portion 44 laterally protrudes on each side of trench 42 by an extra length O. Preferably, surface 12 is substantially planar at the level of trench 42 and the upper surface of insulating portion 44 is substantially coplanar with surface 12. This means that insulating portion 44 forms neither a bulged area nor a depression on surface 12. This enables to ease the carrying out of the subsequent steps of the method of manufacturing electronic circuit 40, particularly since subsequent layer deposition steps will be carried out on a substantially planar surface.

FIG. 3 shows an embodiment of an electronic circuit 45 comprising all the elements of electronic circuit 40, with the difference that insulating portion 44 only covers core 26, insulating portion 24 extending all the way to surface 12. Width L′ of insulating portion 44 then substantially corresponds to the lateral dimension of core 26.

Substrate 10 may correspond to a monoblock structure or to a layer covering a support made of another material. Substrate 10 is preferably a semiconductor substrate, for example, a substrate made of silicon, of germanium, of silicon carbide, of a III-V compound, such as GaN or GaAs, or a ZnO substrate. Preferably, substrate 10 is a single-crystal silicon substrate. Preferably, it is a semiconductor substrate compatible with manufacturing methods implemented in microelectronics. Substrate 10 may correspond to a multilayer structure of silicon-on-insulator type, also called SOI. As a variation, substrate 10 may correspond to a BSOI (Bonded Silicon On Insulator) structure. As a variation, substrate 10 may correspond to a stack of a plurality of silicon layers having different dopant concentrations, for example, of type P. The thickness of substrate 10 of electronic circuit 45, obtained at the end of the method of manufacturing electronic circuit 45, which, as described in further detail hereafter, comprises a thinning step, may be in the range from 2 μm to 150 μm.

Substrate 10 may be heavily doped, lightly-doped, or non-doped. In the case where the substrate is heavily doped, semiconductor substrate 10 may be doped so as to lower the electric resistivity down to a resistivity close to that of metals, preferably lower than a few mohm·cm. Substrate 10 for example is a heavily-doped substrate having a dopant concentration in the range from 5*10¹⁶ atoms/cm³ to 2*10²⁰ atoms/cm³. In the case where the substrate is lightly-doped of a first conductivity type, for example, with a dopant concentration smaller than or equal to 5*10¹⁶ atoms/cm³, preferably substantially equal to 10¹⁵ atoms/cm³, a doped region of the first conductivity type or of a second conductivity type, opposite to the first type, more heavily-doped than the substrate, which extends in substrate 10 from surface 12, may be provided. In the case of a silicon substrate 10, examples of P-type dopants are boron (B) or indium (In) and examples of N-type dopants are phosphorus (P), arsenic (As), or antimony (Sb).

When present, layer 30 may be made of a material favoring the growth of semiconductor elements, not shown. Layer 30 may correspond to a single layer or to a stack of at least two layers. As an example, layer 30 comprises a nitride, a carbide, or a boride of a transition metal from column IV, V, or VI of the periodic table of elements, or a combination of these compounds. As an example, layer 30 may be made of aluminum nitride (AlN), of aluminum oxide (Al₂O₃), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB₂), of zirconium nitride (ZrN), of silicon carbide (SiC), of tantalum carbo-nitride (TaCN), of magnesium nitride in MgₓN_{y} form, where x is approximately equal to 3 and y is approximately equal to 2, for example, magnesium nitride in form Mg₃N₂. Layer 30 may be doped with the same conductivity type as substrate 10. Layer 30 for example has a thickness in the range from 1 nm to 300 nm, preferably in the range from 10 nm to 60 nm. As a variation, layer 30 may be replaced with pads, having a single-layer or multilayer structure, resting on surface 12 of substrate 10, each semiconductor element resting on one of the pads.

Each insulating layer 32, 34 of the stack of insulating layers may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond. As an example, the thickness of the stack of insulating layers 32, 34 is in the range from 25 nm to 2 μm, for example, equal to approximately 150 nm. Each insulating layer 32, 34 may be formed by a deposition method, particularly a chemical vapor deposition (CVD) method, particularly a plasma-enhanced chemical vapor deposition (PECVD) method, for example, at temperatures in the range from 200° C. to 450° C., or a sub-atmospheric chemical vapor deposition (SACVD) method. However, other deposition methods may be implemented.

Insulating layer 35 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), of diamond or of an electrically-insulating polymer. Insulating layer 35 may be formed by the methods previously described for layers 32 and 34.

Insulating layer 24 of trench 42 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond. Preferably, insulating layer 24 is made of silicon oxide. Preferably, insulating layer 24 is made of thermal silicon oxide. Insulating layer 24 may be formed by a deposition method, particularly a CVD-type method, particularly by PECVD-type deposition, for example, at temperatures in the range from 200° C. to 450° C., or of SACVD type. However, other deposition methods may be implemented. Insulating layer 24 may be formed by thermal oxidation, particularly at temperatures in the range from 900° C. to 1100° C. Dry or wet thermal oxidation methods may be used. Preferably, insulating layer 24 is formed by thermal oxidation.

Insulating portion 44 of trench 42 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (particularly of general formula SiOₓN_{y}, for example, Si₂ON₂), of hafnium oxide (HfO₂), or of diamond. Preferably, insulating portion 44 is made of silicon oxide. Preferably, insulating portion 44 is made of thermal silicon oxide. Insulating portion 44 may be formed by a deposition method, particularly a method of chemical vapor deposition (CVD) type, particularly by plasma-enhanced chemical vapor deposition (PECVD), for example, at temperatures in the range from 200° C. to 450° C. Insulating portion 44 may be formed by thermal oxidation, particularly at temperatures in the range from 900° C. to 1100° C. Dry or wet thermal oxidation methods may be used. Preferably, insulating portion 44 is formed by thermal oxidation. According to another embodiment, insulating portion 44 is formed by the deposition of a layer SiO₂ followed by a high-temperature anneal (for example, between 700° C. and 1000° C.) to increase the oxide density. This advantageously enables to avoid the diffusion of dopants from substrate 10 and from core 26 into insulating portion 44, which might decrease the breakdown voltage of insulating portion 44.

Core 26 is preferably made of a semiconductor material, for example, made of silicon, of germanium, of silicon carbide, of a III-V compound, such as GaN or GaAs, or a II-VI compound such as ZnO. Preferably, core 26 is made of polysilicon. Preferably, it is a material compatible with manufacturing methods implemented in microelectronics. Core 26 may correspond to a multilayer structure of different semiconductor materials. Core 26 may be heavily doped, lightly doped, or non-doped.

Dimensions L, E, L′, P, and P′ vary according to the targeted applications. According to an embodiment, width L of trench 42 varies from 0.5 μm to 10 μm and preferably from 2 μm to 4 μm. According to an embodiment, thickness E of insulating layer 24 varies from 50 nm to 1000 nm. Thickness P of substrate 10 after the thinning varies from 2 μm to 150 μm. Aspect ratio P/L may be in the range from 1 to 40, for example, equal to approximately 25. According to an embodiment, depth P′ of insulating portion 44 varies from 50 nm to 1000 nm. In the embodiment shown in FIG. 2, lateral width L′ of insulating portion 44 may be greater than or equal to width L of trench 42. According to an embodiment, the extra length O of insulating portion 44 on each side with respect to the rest of trench 42 varies from 0 to 5 μm. In the embodiment shows in FIG. 3, lateral width L′ of insulating portion 44 is smaller than width L of trench 42.

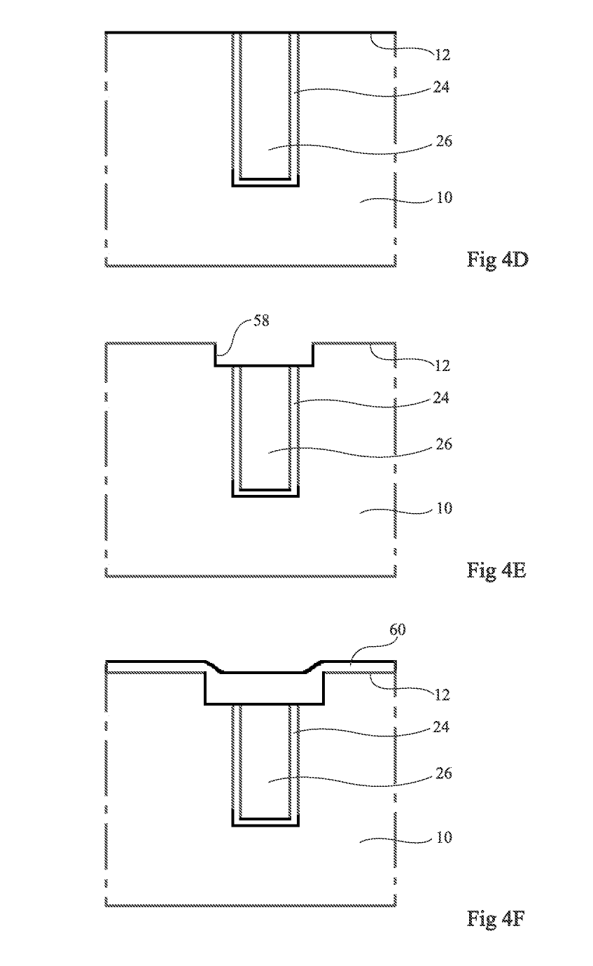

FIGS. 4A to 4G are partial simplified cross-section views of structures obtained at successive steps of an embodiment of a method of manufacturing the electrical insulation trench 42 of electronic circuit 40 of FIG. 2.

FIG. 4A shows the structure obtained after the forming of an opening 50 extending in substrate 10 from surface 12 to the desired location of trench 42, the depth and the width of opening 50 being selected according to the desired dimensions of the trench and to the implemented methods. Opening 50 may be formed by photolithography steps, comprising depositing a resin layer on surface 12, forming an opening into the resin layer on the desired location of opening 50, etching opening 50 into substrate 10 in continuation of the opening formed in the resin layer, and removing the resin layer. As an example, opening 50 may be formed by dry etching. It is possible, if need be, to provide forming a hard mask before the lithography steps.

FIG. 4B shows the structure obtained after the forming of an insulating layer 52, for example by a thermal oxidation step, on surface 12 and in opening 50. The thermal oxidation method causes the turning of a portion of substrate 10 into an oxide, and thus a displacement of surface 12.

FIG. 4C shows the structure obtained after the deposition over the entire structure of a layer 54 of the filling material covering surface 12 and substantially totally filling opening 50.

FIG. 4D shows the structure obtained after the removal of the materials above surface 12 to only keep insulating layer 24 and core 26. The removal step may comprise a step of chemical mechanical polishing (CMP) of insulating layer 52 and of the layer of filling material 54 down to surface 12.

FIG. 4E shows the structure obtained after the forming of an opening 58 extending in substrate 10 from surface 12 to the desired location of portion 44, the depth and the width of opening 58 being slightly smaller than the desired width L′ and depth P′ of portion 44. Opening 58 may be formed by photolithography steps, comprising depositing a resin layer on surface 12, forming an opening into the resin layer on the desired location of opening 58, etching opening 58 into substrate 10 in continuation with the opening formed in the resin layer, and removing the resin layer. As an example, opening 58 may be formed by dry etching. The speed of the etching of the material forming substrate 10 may be different from the speed of the etching of the material forming insulating layer 52 and also different from the filling material etch speed. Thereby, the bottom of opening 58 may be non-planar.

FIG. 4F shows the structure obtained after the forming of an insulating layer 60, for example, by chemical vapor deposition method of PECVD or SACVD type. However, other CVD-type deposition methods may be implemented. As a variation, a step of thermal oxidation, on surface 12 and in opening 58, may be implemented. The thermal oxidation step is for example carried out between 900° C. and 1100° C. During the thermal oxidation step, there is no oxide growth at the level of the end of insulating layer 24 flush with opening 58. However, this vacuum is filled with the oxide which grows from substrate 10 and/or core 26. The deposition method may be followed by an anneal at high temperature, preferably higher than 500° C., for example between 700° C. and 1000° C.

FIG. 4G shows the structure obtained after the etching of the portions of insulating layer 60 outside of opening 58 to only keep insulating portion 44. The etch step may comprise a step of chemical mechanical polishing of insulating layer 60 down to surface 12.

The method further comprises at least subsequent steps of forming layers 30, 32, 34, a step of forming the optoelectronic components, a step of thinning substrate 10 on the side of the surface opposite to surface 12, the thickness of substrate 10 being decreased at least to reach insulating layer 24, and a step of forming layer 35 and possibly contacts pads through layer 35.

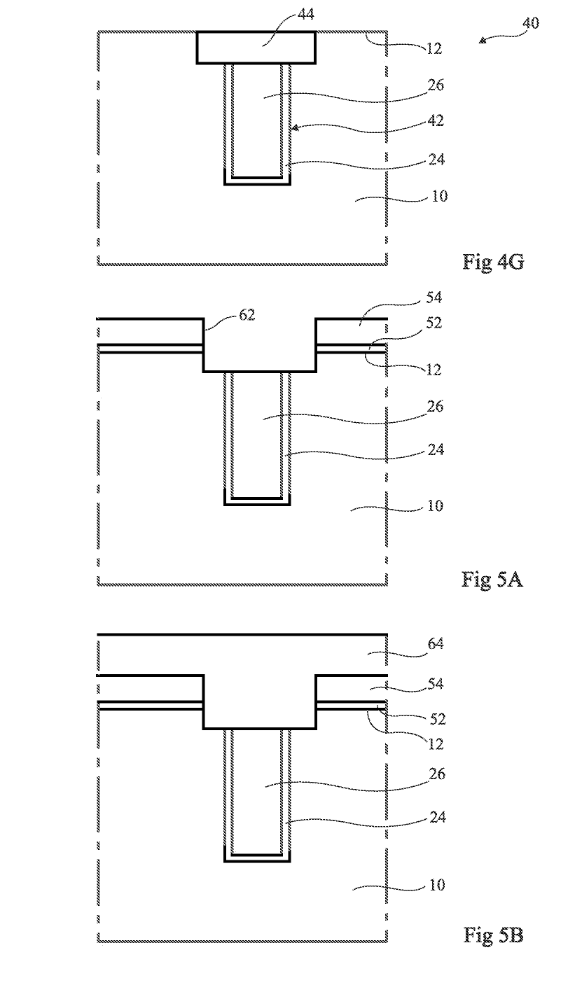

FIGS. 5A to 5C are partial simplified cross-section views of structures obtained at successive steps of another embodiment of a method of manufacturing the electrical insulation trench 42 of the electronic circuit 40 of FIG. 2.

The initial steps of the method are the same as those previously described in relation with FIGS. 4A to 4C.

FIG. 5A shows the structure obtained after the forming of an opening 62 extending in insulating layer 52, in the layer of filling material 54, and in substrate 10. The width and the depth of opening 62 in substrate 10 are slightly smaller than the desired dimensions of insulating portion 44. Opening 62 may be formed by photolithography steps comprising the deposition of a resin layer on the layer of filling material 54, the forming of an opening into the resin layer on the desired location of opening 62, the etching of opening 62 in continuation of the opening formed in the resin layer, and the removal of the resin layer. Opening 62 may be formed by a dry etching.

FIG. 5B shows the structure obtained after the forming of an insulating layer 64, for example, by a thermal oxidation step, on the layer of filling material 54 and in opening 62. The thermal oxidation step is for example carried out between 900° C. and 1100° C. As a variation, a method of chemical vapor deposition of PECVD or SACVD type may be implemented. However, other CVD-type deposition methods may be implemented. The deposition method may be followed by a high-temperature anneal, preferably greater than 500° C., for example, between 700° C. and 1000° C.

FIG. 5C shows the structure obtained after the etching of the portions of insulating layer 64, of the layer of filling material 54, and of insulating layer 52 outside of opening 62 to only keep insulating portion 44 which is buried with respect to surface 12. The etch step may comprise a step of chemical mechanical polishing of layers 64, 54, and 52 down to surface 12.

The method further comprises at least subsequent steps of forming layers 30, 32, 34, a step of forming the optoelectronic components, a step of thinning substrate 10 on the side of the surface opposite to surface 12, the thickness of substrate 10 being decreased at least to reach insulating layer 24, and a step of forming layer 35 and possibly contacts pads through layer 35.

The embodiment of the method of manufacturing trench 42 previously described in relation with FIGS. 5A to 5C has the advantage of comprising one less CMP etch step than the embodiment of the method of manufacturing trench 42 previously described in relation with FIGS. 4A to 4G. The embodiment of the method of manufacturing trench 42 previously described in relation with FIGS. 4A to 4G has the advantage that the etching carried out at the step described in relation with FIG. 4E is shallower than the etching performed at the step described in relation with FIG. 5A of the embodiment of the method of manufacturing trench 42 previously described in relation with FIGS. 5A to 5C.

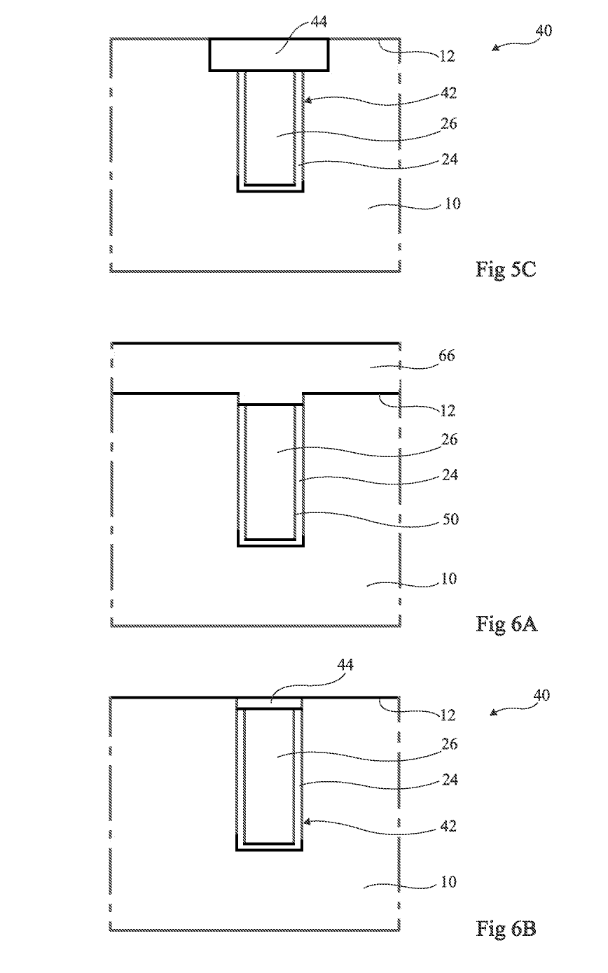

FIGS. 6A and 6B are partial simplified cross-section views of structures obtained at successive steps of another embodiment of a method of manufacturing the electrical insulation trench 42 of the electronic circuit 40 of FIG. 3.

The initial steps of the method are the same as those previously described in relation with FIGS. 4A to 4C.

FIG. 6A shows the structure obtained after the forming of an insulating layer 66 by a thermal oxidation step. The thermal oxidation step is for example carried out between 900° C. and 1100° C. The thermal oxidation causes the transformation of a portion of semiconductor layer 54 of the filling material into an electrically-insulating material. According to the conditions in which the thermal oxidation is performed, insulating layer 52 may play the role of the stop layer for the progression of the oxidation reaction. Thereby, the thermal oxidation is stopped on surface 12 of substrate and only makes headway in the portion of semiconductor layer 54 present in opening 50. Further, as shown in FIG. 6A, insulating layer 66 partly forms in opening 50 without however laterally extending beyond opening 50.

According to the conditions in which the thermal oxidation is performed, it is possible for insulating layer 52 not to stop the progression front of the oxidation reaction. Given that semiconductor layer 54 forms a recess opposite opening 50, during the progress of the oxidation edge of layer 54, the penetration of insulating layer 66 into opening 50 at the top thereof can be observed before the progression front reaches surface 12. In this case, insulating layer 66, which partly forms in opening 50, may laterally extend beyond opening 50.

The conditions of the thermal oxidation are defined so that insulating layer 66 penetrates into opening 50 down to a depth corresponding to the desired depth P′ of insulating portion 44.

FIG. 6B shows the structure obtained after the etching of the portions of insulating layer 66 outside of opening 50 to only keep insulating portion 44. The etch step may comprise a chemical mechanical polishing step.

The method further comprises at least subsequent steps of forming layers 30, 32, 34, a step of forming the optoelectronic components, a step of thinning substrate 10 on the side of the surface opposite to surface 12, the thickness of substrate 10 being decreased at least to reach insulating layer 24, and a step of forming layer 35 and possibly contacts pads through layer 35.

The embodiment of the method of manufacturing trench 42 previously described in relation with FIGS. 6A and 6B has the advantage of comprising no CMP steps or additional photolithography steps with respect to an embodiment of a method of manufacturing trench 14 shown in FIG. 1, which comprises the steps previously described in relation with FIGS. 4A to 4D.

The embodiments of the manufacturing method previously described in relation with FIGS. 4A to 4G and 5A to 5C have the advantage that the thermal oxidation step must be formed across a smaller thickness than the thermal oxidation step carried out during the embodiment of the manufacturing method previously described in relation with FIGS. 6A and 6B.

Advantageously, in the previously-described embodiments, insulating portion 44 is flush with the surface of substrate 10, that is, the upper surface of portion 44 is substantially coplanar with surface 12 of substrate 10. The forming of insulating portion 44 advantageously does not cause the forming of depressions or of raised portions on surface 12 of substrate 10. This eases the implementation of the subsequent steps of the electronic circuit manufacturing method.

Specific embodiments have been described. Although, in the previously-described embodiments, insulating portion 44 is formed by thermal oxidation, insulating portion 44 may be formed by any type of insulating layer forming method, particularly by deposition methods. However, insulating portion 44 is preferably formed by thermal oxidation since the obtained insulating material has good electronic properties, and particularly few electrically-active defects.

1. An electronic device comprising a semiconductor substrate having first and second opposite surfaces and comprising an electrical insulation trench extending in the substrate from the first surface to the second surface, the electrical insulation trench comprising lateral walls, an electrically-insulating layer covering the lateral walls, and a core made of a filling material separated from the substrate by the insulating layer and comprising an electrically-insulating portion extending in the substrate from the first surface and covering the core.

2. The electronic device of claim 1, wherein the first surface is planar at the location of the electrical insulation trench.

3. The electronic device of claim 1, wherein the insulating portion is a thermal oxide.

4. The electronic device of claim 1, wherein the insulating portion is made of silicon oxide.

5. The electronic device of claim 1, wherein the filling material is polysilicon.

6. The electronic device of claim 1, wherein the electrically-insulating portion extends laterally in the substrate with respect to the rest of the electrical insulation trench.

7. The electronic device of claim 1, comprising at least first and second optoelectronic components capable of emitting an electromagnetic radiation or of absorbing an electromagnetic radiation, the first optoelectronic component resting on a first portion of the substrate and the second optoelectronic component resting on a second portion of the substrate, the electrical insulation trench separating the first portion from the second portion.

8. A method of manufacturing the electronic device of claim 1, comprising the steps of:
(a) forming a first opening into the substrate from the first surface;
(b) forming a layer of the material of the electrically-insulating layer in the first opening and on the first surface;
(c) forming a layer of the filling material in the opening and on the first surface; and
(d) forming the insulating portion.

9. The method of claim 8, wherein step (d) comprises a thermal oxidation step.

10. The method of claim 8, wherein step (d) comprises a step of chemical vapor deposition followed by a step of thermal anneal at more than 500° C.

11. The method of claim 8, further comprising step (e) of etching portions of the layer of the material of the electrically-insulating layer and of the layer of the filling material present on the first surface.

12. The method of claim 11, wherein step (e) is carried out before step (d).

13. The method of claim 11, wherein step (d) is carried out before step (e).

14. The method of claim 13, further comprising forming, before step (d), a second opening into the layer of the material of the electrically-insulating layer, the layer of the filling material on the first surface and the substrate at the location of the insulating portion.
